(19) United States
(12) Patent Application Publication
(10) Pub. No.: US 2007/0200202 A1
(43) Pub. Date: Aug. 30, 2007

(54) Phase change memory structure having an electrically formed constriction

(75) Inventors: Janusz Jozef Nowak, Highland Mills, NY (US); Yu Lu, Hopewell Junction, NY (US)

Correspondence Address: RYAN, MASON & LEWIS, LLP, 90 FOREST AVENUE, LOCUST VALLEY, NY, 11560, US

(73) Assignee: International Business Machines Corporation, Armonk, NY (US)

(21) Appl. No.: 11/364,315

(22) Filed: Feb. 28, 2006

(51) Int. Cl. H01L 29/12

(52) U.S. Cl. 257/613

(57) ABSTRACT

A PCM structure configurable for use as a nonvolatile storage element includes a first electrode, a first phase change material layer formed on at least a portion of an upper surface of the first electrode, at least one insulating layer formed on an upper surface of the first phase change material layer, at least a second phase change material layer formed on an upper surface of the at least first insulating layer, and a second electrode formed on at least a portion of an upper surface of the at least second phase change material layer. The insulating layer is configurable for forming an aperture therethrough in response to a first signal of a prescribed level applied between the first and second electrodes, the aperture constricting a flow of current in the PCM structure to thereby create a region of localized heating in the first and second phase change material layers in response to a second signal applied between the first and second electrodes.

### FIELD OF THE INVENTION

The present invention relates generally to memory devices, and more particularly relates to phase change memory cells.

### BACKGROUND OF THE INVENTION

Non-volatile memory is an integral part of many electronic devices from mobile phones, digital cameras, and set-top boxes, to automotive engine controllers primarily because of its ability to store data even when power is turned off. One type of non-volatile memory, namely, phase change memory (PCM), is aimed at eventually supplanting flash memory technology which is used abundantly in such electronic devices. Modern phase change random access memory (PRAM) typically requires that a PCM cell employed therein be compatible with existing field-effect transistor (FET) technology. However, PCM cell volume must be very small so as to ensure that set and reset currents in the PCM cell are smaller then a maximum FET current, which is difficult to achieve using present complementary metal-oxide semiconductor (CMOS) fabrication technology, such as, for example, a 90 nanometer (nm) process.

As is known, PCM cells are generally based on storage elements which utilize a class of materials, such as chalcogenides, that has the property of switching between two distinct states, the electrical resistance of which varies according to the crystallographic structure of the material. A high-resistance, reset state is obtained when an active region of the phase change (PC) material is in an amorphous phase, whereas a low-resistance, set state is obtained when the PC material is in a crystalline or polycrystalline phase. The PC material can be selectively switched between the two phases by application of set and reset currents to the PCM cell.

Reducing the amount of current required by a PC material layer to change its crystalline phase can beneficially decrease power dissipation and improve reliability during operation of the PCM cell. Consequently, attempts have been made to define current flow in the PCM cell so as to provide more efficient self-heating (e.g., Joule heating) of the PC material in the cell. Existing solutions for defining current flow in a PCM cell, which in turn defines an active PCM cell volume, rely predominantly on pushing lithography and etching capabilities to their limits. Presently, existing lithography, including, for example, deep ultraviolet (DUV), e-beam, etc., is limited to a line resolution of about 45 nm. Such lithography techniques are already challenging, especially when forming small features having an island shape (preferably circular).

In particular, one of the smallest elements in a conventional PCM cell is a heater which is typically located on one side of the PCM material. The small heater is often ineffective and challenging to manufacture, and thus adds significantly to the cost of the PCM cell. In order to achieve satisfactory results using small set/reset currents, the heater in the PCM cell needs to be localized well inside the PCM material. Moreover, a common failure mechanism in PCM cells results from an open circuit condition due primarily to repeated stress associated with a set/reset operation, and therefore it is even more desirable to minimize the set/reset currents in the PCM cell so as to ensure reliability of the cell.

Accordingly, there exists a need for improved techniques for defining current flow in a PCM cell that does not suffer from one or more of the problems exhibited by conventional PCM cells.

### SUMMARY OF THE INVENTION

The present invention meets the above-noted need by providing, in an illustrative embodiment, a PCM structure which advantageously includes a current constriction formed within phase change material in the PCM structure for defining current flow therein. The constriction, which may be a pinhole or other aperture, is preferably formed electrically, rather than by lithography, thus allowing the size of the constriction to be made substantially smaller than what would otherwise be achievable using a standard lithography process.

The present invention describes an illustrative PCM cell that includes two phase change material layers separated by a thin insulation layer. An ultra small pinhole (e.g., about 20 nm or less) in the insulation layer is preferably created by applying an external signal of sufficient magnitude between two electrodes of the PCM cell. The pinhole in the insulation layer is usually conductive and the remaining oxide layer forms the current constriction to limit an active phase change material volume in the PCM cell. When the external signal is applied to the PCM cell, current becomes highly concentrated in and around the pinhole. The pinhole thus serves as a “nano-heater” surrounded by phase change material, thereby eliminating the need for fabricating a separate heater element in the PCM cell.

In accordance with one aspect of the invention, a PCM structure configurable for use as a nonvolatile storage element includes a first electrode, a first phase change material layer formed on at least a portion of an upper surface of the first electrode, at least one insulating layer formed on an upper surface of the first phase change material layer, at least a second phase change material layer formed on an upper surface of the at least first insulating layer, and a second electrode formed on at least a portion of an upper surface of the at least second phase change material layer. The insulating layer is configurable for forming an aperture therethrough in response to a first signal of a prescribed level applied between the first and second electrodes, the aperture constricting a flow of current in the PCM structure to thereby create a region of localized heating in the first and second phase change material layers in response to a second signal applied between the first and second electrodes.

In accordance with another aspect of the invention, a nonvolatile storage cell includes at least one PCM structure. The at least one PCM structure includes a first electrode, a first phase change material layer formed on at least a portion of an upper surface of the first electrode, at least one insulating layer formed on an upper surface of the first phase change material layer, at least a second phase change material layer formed on an upper surface of the at least first insulating layer, and a second electrode formed on at least a portion of an upper surface of the at least second phase change material layer. The insulating layer includes an aperture formed therethrough for restricting a flow of current in the PCM structure to thereby create a region of localized heating in the first and second phase change material layers in response to a signal applied between the first and second electrodes.

In accordance with yet another aspect of the invention, a method of forming a nonvolatile PCM cell includes the steps of: forming a first electrode; forming a first phase change material layer on at least a portion of an upper surface of the first electrode; forming at least one insulating layer on an upper surface of the first phase change material layer; forming at least a second phase change material layer on an upper surface of the at least first insulating layer; forming a second electrode on at least a portion of an upper surface of the at least second phase change material layer; and forming an aperture through the at least one insulating layer in response to a first signal of a prescribed level applied between the first and second electrodes. The aperture is adapted to constrict a flow of current in the PCM cell to thereby create a region of localized heating in at least a portion of the first and second phase change material layers in response to a second signal applied between the first and second electrodes.

These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 is a cross-sectional view depicting an exemplary PCM cell, formed in accordance with an embodiment of the present invention.

FIG. 2 is top plan view depicting the exemplary PCM cell shown in FIG. 1, taken along line 1-1′.

FIG. 3 is a cross-sectional view depicting an exemplary PCM cell, formed in accordance with another embodiment of the present invention.

FIG. 4 is a cross-sectional view depicting an exemplary methodology for repairing a defective PCM cell, in accordance with another aspect of the present invention.

FIG. 5 is a schematic diagram illustrating an exemplary nonvolatile memory circuit in which the PCM cells of the present invention can be employed, in accordance with another aspect of the present invention.

### DETAILED DESCRIPTION OF PREFERRED EMBODIMENTS

The present invention will be described herein in the context of illustrative PCM cells for use, for example, in a non-volatile memory array. It should be understood, however, that the present invention is not limited to the particular PCM cell arrangements shown. Furthermore, the techniques of the present invention are not limited to a PCM application. Rather, the invention is generally applicable to techniques for more efficiently defining current flow in PC material. The techniques of the present invention can be advantageously employed in other memory applications, such as, for example, storage elements comprising solid electrolyte, polymer and molecular switches, as will become apparent to those skilled in the art.

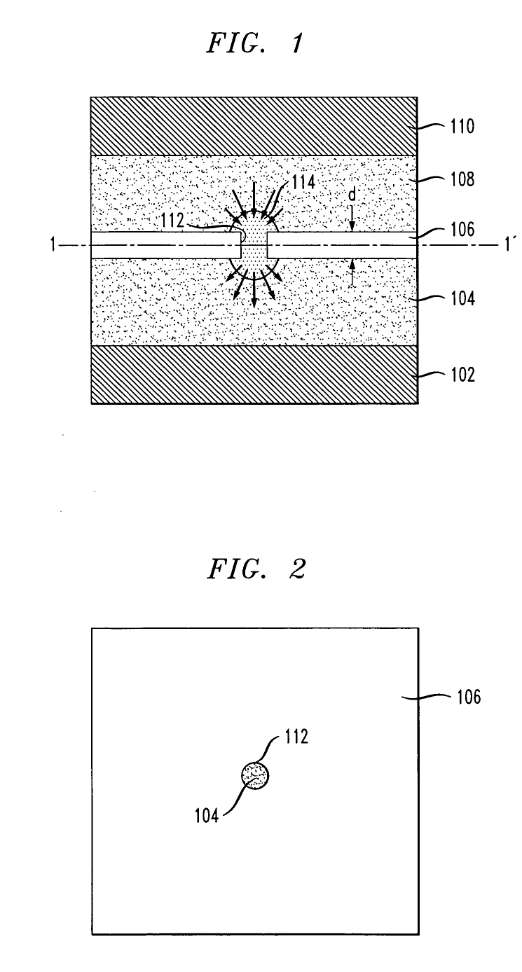

FIG. 1 is a cross-sectional view depicting an exemplary PCM structure 100 formed in accordance with one embodiment of the present invention. The exemplary PCM structure 100 comprises a first electrode 102, a first PC material layer 104 formed on an upper surface of at least a portion of the first electrode, an insulating layer 106, which may also be referred to herein as a barrier layer, a second PC material layer 108 formed on an upper surface of the insulating layer, and a second electrode 110 formed on an upper surface of at least a portion of the second PC material layer. It is to be appreciated that, in accordance with other aspects of the invention, the PCM structure 100 may comprise more or less than two PC material layers and/or more than one insulating layer.

The first and second electrodes 102, 110 are preferably formed of an electrically conductive material, such as, but not limited to, a metal, an alloy, a metal oxynitride, and/or a conductive carbon compound. For example, the first and second electrodes 102, 110 may comprise aluminum (Al), tungsten (W), titanium (Ti), tantalum (Ta), titanium nitride (TiN), tantalum nitride (TaN), molybdenum (Mo), niobium (Nb), WN, MoN, NbN, TiSiN, TiAlN, MoAlN, TaSiN, TaAlN, TiW, TaSi, and/or TiSi. First and second electrodes 102, 110 provide access to the PCM structure 100 by providing electrical connection to the first and second PC material layers 104, 108, respectively.

The first and second PC material layers 104, 108 are preferably comprised of a chalcogenide material, or alternative material exhibiting two distinct phases of differing resistivities. Chalcogenide materials suitable for use with the present invention include, but are not limited to, tellurium (Te), selenium (Se), germanium (Ge), antimony (Sb), bismuth (Bi), lead (Pb), tin (Sn), arsenic (As), sulfur (S), silicon (Si), phosphorus (P), any mixture thereof, and/or any alloy thereof. The two PC material layers 104, 108 need not be formed of the same material. In a preferred embodiment of the invention, the first and second PC material layers 104, 108 comprise Ge₂Sb₂Te₅ (GST). The PC material may be deposited on their respective surfaces using a standard deposition process (e.g., sputtering, chemical vapor deposition (CVD), etc.), although the invention is not limited to forming the PC material layers 104, 108 in this manner.

The insulating layer 106 is preferably formed of an oxide (e.g., silicon dioxide, aluminum oxide, etc.), or an alternative material which is substantially electrically non-conductive (e.g., having a resistance in the gigaohm range). The insulating layer 106 may be formed using, for example, a standard oxide growth process, although alternative methodologies for forming the insulating layer are similarly contemplated (e.g., deposition process). The material used to form insulating layer 106 should be stable at temperatures higher than a melting point of the PC material at the set and reset temperatures, which may be greater than about 500 degrees Celsius, so that compounds do not form between the PC material and the insulating layer material during operation of the PCM structure. Additionally, the insulating layer 106 and the PC material layers 104, 108 should be mutually insoluble so as to further reduce the likelihood that compounds form between the PC material and the insulating layer. The cross-sectional thickness, d, of the insulating layer 106 is preferably about 10 to about 30 angstroms, although the invention is not limited to any particular thickness.

After the PCM structure 100 is initially fabricated, insulating layer 106 may be continuous between the first and second PC material layers 104, 108, thereby forming a barrier for electrically isolating the first PC material layer from the second PC material layer. The PCM structure, in this instance, will exhibit a very high resistance (e.g., gigaohms). However, in order for the PCM structure 100 to function efficiently as a storage element, an aperture 112 is preferably formed through the insulating layer 106 so that current can flow between the first and second electrodes 102, 110. The term “aperture” as used herein is intended to refer to an opening, hole, slit, channel, etc., of essentially any size and/or shape formed through the insulating layer. In a preferred embodiment, the aperture 112 is a substantially circular pinhole formed through the insulating layer 106 through which the first PC material layer 104 below is visible, as shown in the top plan view of FIG. 2.

With continued reference to FIG. 1, the aperture 112, which is substantially more conductive than the remaining insulating layer 106, is preferably configured so as to create a constriction for limiting an active PC material volume 114 and for defining current flow in the first and second PC material layers 104, 108. Since a diameter of the aperture is preferably about 20 nm or less, the constriction may be referred to as a nano-constriction. When a signal is applied to the first and second electrodes 102, 110 of the PCM structure 100, a region of the first and second PC material layers 104, 108 proximate the aperture 112 will experience a current density which is substantially higher compared to the current density in the remainder of the PC material as a result of the constriction. The concentration of current in and around the aperture 112 will, in turn, result in localized self-heating of the PC material. When the applied signal reaches a certain threshold so as to cause a localized heating of the PC material proximate the aperture 112 to a certain critical temperature value, a phase transmition of at least a portion of the PC material will occur. Thus, in accordance with an important aspect of the invention, the aperture 112 itself serves as a heater surrounded by PC material, thereby eliminating the need for fabricating a separate heater element in the PCM structure 100.

It is desirable to be able to accurately control the size (e.g., diameter) of the aperture 112 in the PCM structure. As previously stated, conventional lithography techniques are presently limited to feature dimensions of about 45 nm or larger. Thus, in order to form an aperture having, for example, a diameter of less than about 20 nm, a different approach is needed. In accordance with another aspect of the invention, the aperture 112 is preferably formed electrically rather than using lithography. Specifically, when a signal (e.g., voltage or current) of appropriate magnitude is applied across the insulating layer 106, dielectric breakdown will occur and a pinhole or other conductive path, such as aperture 112, will be formed through the insulating layer. The voltage at which dielectric breakdown occurs will typically depend on one or more characteristics of the insulating layer 106, including, but not limited to, the cross-sectional thickness d of the insulating layer and/or the type of material forming the insulating layer.

The size of the pinhole created during dielectric breakdown depends primarily on the amount of energy released during the breakdown event. Techniques for controlling the size of pinholes in ultra thin barriers are known, as described, for example, in an article by Bryan Oliver et al., entitled “Two Breakdown Mechanisms in Ultrathin Alumina Barrier Magnetic Tunnel Junctions,” Journal of Applied Physics, Vol. 95, Issue 3, pp. 1315-1322 (February 2004), the disclosure of which is incorporated by reference herein. Basically, the pinhole grows primarily as a result of a thermal mechanism (e.g., melting of the insulating layer) when a critical current density at the pinhole is reached. Thus, for a given type and thickness of material forming insulating layer 106, a nanometer scale aperture (e.g., pinhole) can be created by appropriate selection of amplitude and/or duration of a current pulse applied to the PCM structure 100. Using this approach, an aperture can be formed in the insulating layer 106 with dimensions as small as only a few nanometers in diameter. This creates a constriction that allows an extremely accurate definition of current flow in the PC material layers 104, 108 which, in turn, enables set/reset currents in the PCM structure 100 to be beneficially reduced. While the invention is not limited to any particular thickness of the insulating layer, as the thickness of the insulating layer increases (e.g., greater than about 40 angstroms), it becomes more difficult to control the size of the aperture through dielectric breakdown.

The aperture 112 is preferably formed by applying a formatting signal between the first and second electrodes 102, 110 of the PCM structure 100. The formatting signal preferably comprises one or more voltage or current pulses of a prescribed amplitude and duration (pulse width). The duration of the formatting pulses is preferably selected to be about a few nanoseconds and may be about a few milliseconds in duration, although the formatting signal is not limited to pulses of any particular duration. Likewise, the amplitude of the formatting signal is not limited to any particular voltage or current level. The amplitude and duration of the pulses are preferably selected so as to control the size of the aperture formed in the insulating layer 106 as desired and will be a function of one or more characteristics of the insulating layer, including, but not limited to, the cross-sectional thickness and type of material of the insulating layer.

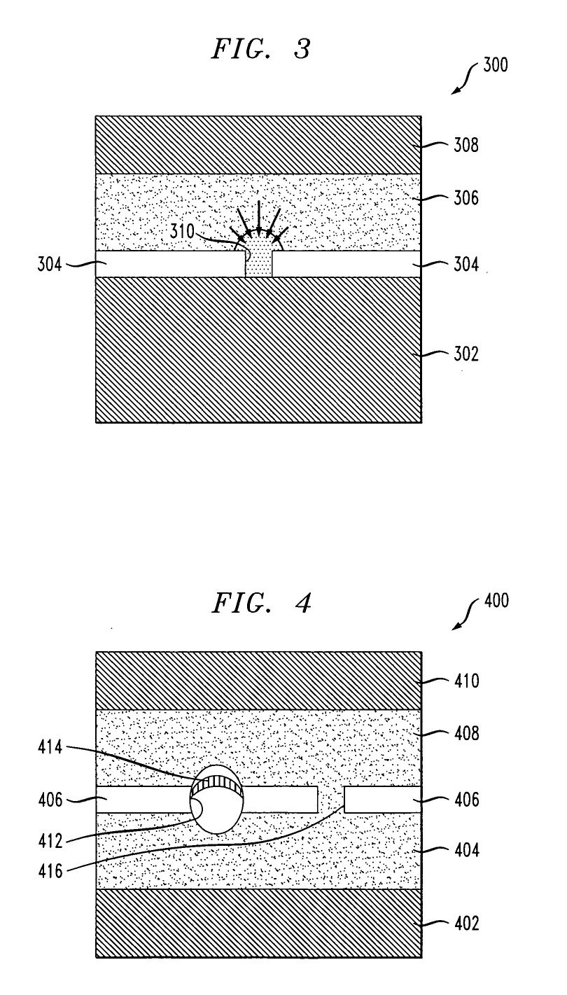

It is to be understood that the formatting procedure used to form the aperture 106 may be performed during a final test step after fabrication of the PCM structure 100 (e.g., at the wafer level). Alternatively, the formatting procedure can be performed during or after packaging (e.g., at package level). Regardless of when formatting is performed, the formatting procedure, in the context of a memory application, preferably involves addressing a given one of the PCM structures and applying a formatting signal to the given PCM structure to form the aperture therein. Formatting circuitry may be included into the chip design and, as a result, the formatting procedure can be repeated multiple times as required. In this manner, aging or defective PCM cells can be repaired, as will be described in conjunction with FIG. 3, and a higher performance can be beneficially maintained over the life of the memory device. Furthermore, the formatting procedure can be used to selectively control the size of the aperture 112 and thereby control a resistance of the PCM structure 100.

Although shown in the figure as being substantially centered along the insulating layer 106, it is not critical where in the insulation layer the aperture 112 is formed. Most likely, the aperture will be formed, in response to the applied signal, in a region of the insulating layer 106 having the lowest resistivity. This may occur, for instance, in an area of the insulating layer 106 having the smallest cross-sectional thickness d. While typically only a single aperture will be formed in the insulating layer during a given dielectric breakdown process, it is contemplated that multiple apertures can be formed. While rare, multiple apertures can be formed during the same breakdown cycle in portions of the insulating layer exhibiting substantially the same weaknesses (e.g., resistivity). By controlling the thickness of the insulating layer 106, the formation of the aperture 112 can be advantageously directed to a particular region of the insulating layer. For example, it may not be preferable to form the aperture 112 at the edges of the insulating layer 106, and therefore the thickness d of the insulating layer at the edges can be made greater relative to interior portions of the insulating layer. This will beneficially increase the dielectric breakdown voltage at the edges of the insulating layer 106 to thereby reduce the likelihood that the aperture will be formed at the edges.

While it may be desirable to make the insulating layer 106 as uniform in thickness as possible, this is rarely the case in practice. This is especially true since the insulating layer 106 in PCM structure 100 is formed on the upper surface of first PC material layer 104, which often has a relatively rough topography.

FIG. 3 is a cross-sectional view depicting an exemplary PCM structure 300, formed in accordance with another embodiment of the invention. The exemplary PCM structure 300 includes a first electrode 302, an insulating layer 304 formed on an upper surface of the first electrode, a PC material layer 306 formed on an upper surface of the insulating layer 304, and a second electrode 308 formed on an upper surface of at least a portion of the PC material layer. As apparent from the figure, unlike the PCM structure 100 shown in FIG. 1, PCM structure 300 comprises a only single PC material layer. This configuration provides at least one advantage in that forming the insulating layer 304 directly on the first electrode 302 allows the formation of an insulating layer having a more uniform thickness, since the upper surface of the first electrode, which preferably comprises a metal or other conductive material, is typically more uniform in topology compared to the upper surface of a PC material layer. However, in this configuration, an active volume of the PC material is in contact with first electrode 302, and therefore this PCM configuration may be more prone to certain failure mechanisms found in standard PCM cells.

First and second electrodes 302, 308 may be formed of an electrically material similar to those materials used to form the first and second electrodes 102, 110 of the illustrative PCM structure 100 shown in FIG. 1. PC material layer 306 may be formed in a manner similar to PC material layers 104, 108 of the PCM structure 100 shown in FIG. 1. In a preferred embodiment, PC material layer 306 comprises GST or an alternative chalcogenide material. Likewise, insulating layer 304 preferably comprises an oxide or alternative insulating material, and may be formed in a manner consistent with that used to form the insulating layer 106 in PCM structure 100 depicted in FIG. 1.

An aperture 310 is preferably formed in the insulating layer 304 electrically (e.g., using dielectric breakdown) rather than using lithography, as in a manner consistent with the formation of aperture 106 in the PCM structure 100 of FIG. 1. Some of the advantages of forming the aperture electrically as opposed to using lithography were previously described and include, for instance, the ability to control the size of the aperture 310 to less than a few nanometers. The resolution of conventional lithography techniques are limited to forming features greater than about 45 nm.

A frequent failure mode in state of the art PCM cells involves a delamination of the PC material near an interface with a heater element in the PCM cell, due primarily to the significant volume change associated with the phase transformation. As a result of such failure, the PCM cell becomes highly resistive (e.g., essentially an open circuit). Usually, in the case of these conventional PCM cells, the delamination is permanent and cannot be repaired. However, in accordance with the present invention, delamination of the PC material proximate the interface between the aperture and the PC material can be beneficially repaired, as will be described herein below.

FIG. 4 is a cross-sectional view depicting an exemplary methodology for repairing a defective PCM structure 400, in accordance with another aspect of the present invention. Like the PCM structure 100 shown in FIG. 1, PCM structure 400 preferably comprises a first electrode 402, a first PC material layer 404 formed on an upper surface of at least a portion of the first electrode, an insulating layer 406, which may also be referred to herein as a barrier layer, a second PC material layer 408 formed on an upper surface of the insulating layer, and a second electrode 410 formed on an upper surface of at least a portion of the second PC material layer. An aperture 412 is preferably formed in the insulating layer 406, such as in a manner consistent with that described above in conjunction with PCM structure 100 of FIG. 1.

As apparent from the figure, an area of delamination 414 may form in the crystalline PC material proximate the aperture 412. The delamination 414 effectively blocks the flow of current through the aperture 412, thereby resulting in a high-resistance (e.g., open circuit) PCM structure which fails to function reliably as a storage element. In accordance with a repair methodology of the present invention, a second aperture 416 is preferably formed in a new location in the insulating layer 406. The second aperture 416 may be formed by applying the aforementioned formatting signal between the first and second electrodes 402, 410 of the PCM structure 400. The second aperture 416 bypasses the damaged aperture 412 and allows the PCM structure 400 to function as a normal storage element. The newly formed second aperture 416 will most likely be spaced laterally from the delaminated aperture 412, and its operation will be not be disturbed by the presence of the delaminated aperture.

A particular PCM structure can be repaired multiple times depending on the size of the active PC material volume and the available PC material size. For example, assuming a PCM structure which is 100 nm in diameter and an aperture size of 10 nm in diameter, the reparation process can be repeated in new locations of the insulating layer almost 100 times (about [100 nm/10 nm]²). In this manner, a very robust PCM cell can be created, even from materials which are prone to delamination. Also if a resistance of the PCM structure increases beyond a prescribed threshold value, as can occur as a result of aging and/or other mechanisms, the resistance of the PCM structure can be reduced by changing the size of the aperture (e.g., enlarging the aperture). Thus, a memory cell formed in accordance with the techniques of the present invention will advantageously exhibit a much longer usable lifetime. Moreover, using additional detection circuitry included in a PCM array (e.g., PRAM) which is operative to self-diagnose defective memory cells, the PCM array can be repaired “on the fly” during operation, in accordance with an aspect of the invention.

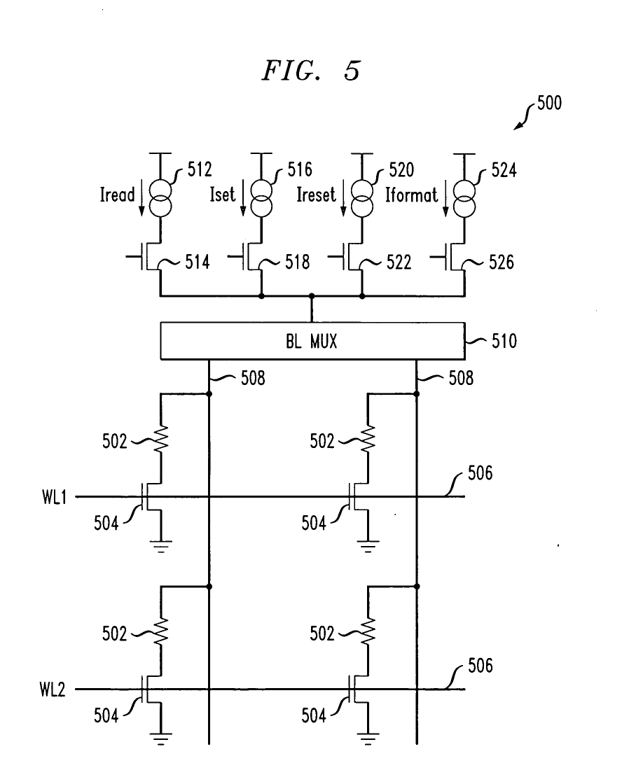

FIG. 5 is a schematic diagram illustrating an exemplary nonvolatile memory circuit 500 in which the PCM structures of the present invention can be employed, in accordance with another aspect of the present invention. The memory circuit 500 preferably comprises a plurality of PCM cells 502, formed in accordance with the techniques of the invention described above, and corresponding access transistors 504 connected thereto. The access transistors 504 are selectively activated by application of appropriate signals, WL1, WL2, to corresponding word lines 506 in the memory circuit 500. Each of the access transistors 504 is preferably operative to connect a first electrode of the corresponding PCM cell 502 to ground, or an alternative voltage source.

Memory circuit 500 further includes a plurality of current sources 512, 516, 520 and 524, supplying currents Iread, Iset, Ireset and Iformat, respectively, to the PCM cells 502 via a bit line multiplexer (BL mux) 510, or an alternative switching arrangement. Each of the current sources 512, 516, 520, 524 is preferably connected to the multiplexer 510 through a corresponding switch, 514, 518, 522 and 526, respectively, which may comprise a transistor as shown. The current Iread is preferably configured for selectively reading a logical state of the PCM cells 502, while the currents Iset and Ireset are preferably configured for performing a set and reset operation, respectively, for selectively writing a logical state of the cells. The current Iformat is preferably the formatting signal used to form an aperture in a selected PCM cell during a formatting procedure, as previously explained.

At least a portion of the methodologies of the present invention may be implemented in an integrated circuit. In forming integrated circuits, a plurality of identical die is typically fabricated in a repeated pattern on a surface of a semiconductor wafer. Each die includes a device described herein, and may include other structures and/or circuits. The individual die are cut or diced from the wafer, then packaged as an integrated circuit. One skilled in the art would know how to dice wafers and package die to produce integrated circuits. Integrated circuits so manufactured are considered part of this invention.

Although illustrative embodiments of the present invention have been described herein with reference to the accompanying drawings, it is to be understood that the invention is not limited to those precise embodiments, and that various other changes and modifications may be made therein by one skilled in the art without departing from the scope of the appended claims.

What is claimed is:

1. A phase change memory (PCM) structure configurable for use as a nonvolatile storage element, the PCM structure comprising:
a first electrode;
a first phase change material layer formed on at least a portion of an upper surface of the first electrode;
at least one insulating layer formed on an upper surface of the first phase change material layer;
at least a second phase change material layer formed on an upper surface of the at least first insulating layer; and
a second electrode formed on at least a portion of an upper surface of the at least second phase change material layer;
wherein the PCM structure is configurable for forming an aperture through the at least one insulating layer in response to a first signal of a prescribed level applied between the first and second electrodes, the aperture being adapted to constrict a flow of current in the PCM structure to thereby create a region of localized heating in at least a portion of the first and second phase change material layers in response to a second signal applied between the first and second electrodes.

2. The structure of claim 1, wherein a size of the aperture is less than about 20 nanometers.

3. The structure of claim 1, wherein at least one of the first and second phase change material layers comprises a chalcogenide material.

4. The structure of claim 1, wherein the prescribed level is greater than or equal to a dielectric breakdown voltage of the at least one insulating layer.

5. The structure of claim 1, wherein the second signal comprises at least one of a set pulse and a reset pulse, the second signal being operative to selectively switch a state of at least a portion of the first and second phase change material layers proximate the aperture, the state of the phase change material layers being indicative of a logical state of the PCM structure.

6. The structure of claim 1, wherein the region of localized heating is substantially confined to a volume of the first and second phase change material layers proximate the aperture.

7. The structure of claim 1, wherein at least one of the first and second electrodes comprises a metal.

8. The structure of claim 1, wherein the at least one insulating layer comprises an oxide.

9. The structure of claim 1, wherein the at least one insulating layer has a cross-sectional thickness of about 20 angstroms to about 40 angstroms.

10. The structure of claim 1, wherein the at least one insulating layer has a cross-sectional thickness proximate exterior edges of the insulating layer that is greater than a cross-sectional thickness of an interior of the insulating layer.

11. The structure of claim 1, wherein the at least one insulating layer has a cross-sectional thickness which is configured such that a likelihood of the aperture being formed proximate an interior portion of the insulating layer is greater than a likelihood of the aperture being formed proximate exterior edges of the insulating layer.

12. A nonvolatile storage cell, comprising:
at least one phase change memory (PCM) structure comprising:
a first electrode;
a first phase change material layer formed on at least a portion of an upper surface of the first electrode;
at least one insulating layer formed on an upper surface of the first phase change material layer, the insulating layer including an aperture formed therethrough for restricting a flow of current in the PCM structure;
at least a second phase change material layer formed on an upper surface of the at least first insulating layer; and
a second electrode formed on at least a portion of an upper surface of the at least second phase change material layer.

13. The storage cell of claim 12, wherein the aperture is formed in the at least one insulating layer by applying a first signal having a first amplitude and a first duration associated therewith between the first and second electrodes, the aperture being adapted to constrict a flow of current in the PCM structure to thereby create a region of localized heating in at least a portion of the first and second phase change material layers in response to a second signal applied between the first and second electrodes.

14. The storage cell of claim 12, wherein the first amplitude is greater than or equal to a dielectric breakdown voltage of the at least one insulating layer.

15. The storage cell of claim 12, wherein a size of the aperture is less than about 20 nanometers.

16. The storage cell of claim 12, wherein the at least one insulating layer has a cross-sectional thickness which is configured such that a likelihood of the aperture being formed proximate an interior portion of the insulating layer is greater than a likelihood of the aperture being formed proximate exterior edges of the insulating layer.

17. The storage cell of claim 12, wherein the region of localized heating is substantially confined to a volume of the first and second phase change material layers proximate the aperture.

18. The storage cell of claim 12, wherein at least one of the first and second phase change material layers comprises a chalcogenide material.

19. An integrated circuit including at least one phase change memory (PCM) structure configurable for use as a nonvolatile storage element, the at least one PCM structure comprising:
a first electrode;
a first phase change material layer formed on at least a portion of an upper surface of the first electrode;
at least one insulating layer formed on an upper surface of the first phase change material layer;
at least a second phase change material layer formed on an upper surface of the at least first insulating layer; and
a second electrode formed on at least a portion of an upper surface of the at least second phase change material layer;
wherein the at least one PCM structure is configurable for forming an aperture through the at least one insulating layer in response to a first signal of a prescribed level applied between the first and second electrodes, the aperture being adapted to constrict a flow of current in the at least one PCM structure to thereby create a region of localized heating in at least a portion of the first and second phase change material layers in response to a second signal applied between the first and second electrodes.

20. A method of forming a nonvolatile phase change memory (PCM) cell, the method comprising the steps of:
forming a first electrode;
forming a first phase change material layer on at least a portion of an upper surface of the first electrode;
forming at least one insulating layer on an upper surface of the first phase change material layer;
forming at least a second phase change material layer on an upper surface of the at least first insulating layer;
forming a second electrode on at least a portion of an upper surface of the at least second phase change material layer; and
forming an aperture through the at least one insulating layer in response to a first signal of a prescribed level applied between the first and second electrodes, the aperture being adapted to constrict a flow of current in the PCM cell to thereby create a region of localized heating in at least a portion of the first and second phase change material layers in response to a second signal applied between the first and second electrodes.
